(19) United States
(12) Patent Application Publication
(10) Pub. No.: US 2023/0162013 A1
(43) Pub. Date: May 25, 2023

(54) SEMICONDUCTOR DEVICE

(71) Applicant: RENESAS ELECTRONICS CORPORATION, Tokyo (JP)

(72) Inventors: Kazuaki TERASHIMA, Tokyo (JP); Atsushi NAKAMURA, Tokyo (JP); Manabu KOIKE, Tokyo (JP)

(21) Appl. No.: 17/954,831

(22) Filed: Sep. 28, 2022

(30) Foreign Application Priority Data
Nov. 22, 2021 (JP) 2021-189169

(51) Int. Cl. G06N 3/063; G06F 5/01; G06F 7/544

(52) U.S. Cl. CPC G06N 3/063; G06F 5/01; G06F 7/5443

(57) ABSTRACT

A semiconductor device according to one embodiment executes a neural network processing. A first shift register sequentially generates a plurality of pieces of quantized input data by quantizing a plurality of pieces of output data sequentially inputted from a first buffer by bit-shifting. A product-sum operator generates operation data by performing a product-sum operation to a plurality of parameters and the plurality of pieces of quantized input data from the first shift register. The second shift register generates the output data by inversely quantizing the operation data from the product-sum operator by bit-shifting, and stores the output data in the first buffer.

### CROSS-REFERENCE TO RELATED APPLICATIONS

The present application claims priority from Japanese Patent Application No. 2021-189169 filed on Nov. 22, 2021, the content of which is hereby incorporated by reference to this application.

### BACKGROUND

The present invention relates to a semiconductor device, for example, a semiconductor device executing a neural network processing.

Patent Document 1 (Japanese Patent Application Laid-Open No. 2019-40403) discloses an image recognition device having a convolutional operation processing circuit that performs calculation by using an integrated coefficient table in order to reduce an amount of calculation of convolutional operations in a CNN (Convolutional Neural Network). The integrated coefficient table holds N × N pieces of data, and each of the N × N pieces of data is configured by a coefficient and a channel number. The convolutional operation processing circuit includes a product operation circuit that executes N × N product operations of an input image and a coefficient in parallel, and a channel selection circuit for performing an accumulation addition operation to its production operation result for each channel number and storing its addition operation result in an output register for each channel number.

### SUMMARY

In a neural network such as a CNN, the floating-point number of parameters such as 32 bits, specifically, weight parameters and bias parameters are obtained by learning. However, in using the floating-point number of parameters to perform a product-sum operation during inference, a circuit area, a processing load, power consumption, and execution time of a product-sum operation unit (called MAC (Multiply ACcumulate operation) circuit) can be increased. Further, required memory capacity and memory bandwidth increase with read or write from temporary buffers of the parameters and the operation results, and the power consumption can also increase.

Therefore, in recent years, attention has been focused on a method of making an inference after quantizing the floating-point number of parameters such as 32 bits into integers of 8 bits or less. In this case, since the MAC circuit may perform integer operations with the small number of bits, the circuit area, processing load, power consumption, and execution time of the MAC circuit can be reduced. However, However, in using the quantization, quantization error varies depending on granularity of quantization, and accuracy of the inference may vary accordingly. Consequently, an efficient mechanism for reducing the quantization error is demanded. Also, reducing the memory bandwidth is required to allow inference to be made with less hardware resources and time.

Other problems and novel features will become apparent from the description of the present specification and the accompanying drawings.

Therefore, a semiconductor device according to one embodiment executes a neural network processing, and includes a first buffer, a first shift register, a product-sum operator, and a second shift register. The first buffer holds output data. The first shift register sequentially generates a plurality of pieces of quantized input data by quantizing a plurality of pieces of output data sequentially inputted from the first buffer by bit-shifting. The product-sum operator generates operation data by performing a product-sum operation to a plurality of parameters and the plurality of pieces of quantized input data from the first shift register. The second shift register generates the output data by inversely quantizing the operation data from the product-sum operator by bit-shifting, and stores the output data in the first buffer.

Using a semiconductor device according to one embodiment makes it possible to provide a mechanism for efficiently reducing the quantization errors in the neural network.

### BRIEF DESCRIPTION OF THE DRAWINGS

FIG. 1 is a schematic diagram showing a configuration example of a main part in a semiconductor device according to a first embodiment.

FIG. 2 is a circuit block diagram showing a detailed configuration example around a neural network engine in FIG. 1.

FIG. 3 is a schematic diagram showing a configuration example of a neural network processed by the neural network engine shown in FIG. 2.

FIG. 4 is a circuit block diagram showing a detailed configuration example around a neural network engine in a semiconductor device according to a second embodiment.

FIG. 5 is a schematic diagram for explaining an operation example of a buffer controller in FIG. 4.

FIG. 6 is a schematic diagram showing a configuration example of a main part in a semiconductor device according to a third embodiment.

FIG. 7 is a circuit block diagram showing a detailed configuration example around a neural network engine in FIG. 6.

FIG. 8 is a circuit block diagram showing a detailed configuration example around a neural network engine in a semiconductor device according to a fourth embodiment.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference characters throughout the drawings for describing the embodiments, and the repetitive description thereof will be omitted. In addition, the description of the same or similar portions is not repeated in principle unless particularly required in the following embodiments.

### First Embodiment

### Outline of Semiconductor Device

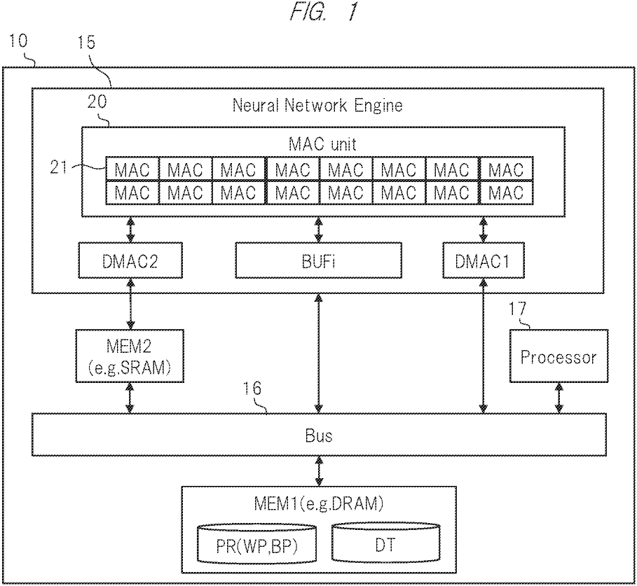

FIG. 1 is a schematic diagram showing a configuration example of a main part in a semiconductor device according to a first embodiment. A semiconductor device 10 shown in FIG. 1 is, for example, a SoC (System on Chip) or the like composed of one semiconductor chip. The semiconductor device 10 is typically mounted in an ECU (Electronic Control Unit) or the like of a vehicle, and provides an ADAS (Advanced Driver Assistance System) function.

The semiconductor device 10 shown in FIG. 1 has a neural network engine 15, a processor 17 such as a CPU (Central Processing Unit), one or more memories MEM1, MEM2, and a system bus 16. The neural network engine 15 executes a processing of a neural network represented by CNN. The memory MEM1 is a DRAM (Dynamic Random Access Memory) or the like, and the memory MEM2 is a cache SRAM (Static Random Access Memory) or the like. The system bus 16 connects the neural network engine 15, the memories MEM1, MEM2, and the processor 17 to one another.

The memory MEM1 holds, for example, a plurality of pieces of data DT composed of pixel values, and a plurality of parameters PR. The parameter PR includes a weight parameter WP and a bias parameter BP. The memory MEM2 is used as a high-speed cache memory for the neural network engine 15. For example, the plurality of pieces of data DT in the memory MEM1 are used in the neural network engine 15 after being copied in the memory MEM2 in advance.

The neural network engine 15 includes a plurality of DMA (Direct Memory Access) controllers DMAC1, DMAC2, a MAC unit 20, and a buffer BUFi. The MAC unit 20 includes a plurality of MAC circuits 21, that is, a plurality of product-sum operators. The DMA controller DMAC1 controls data transfer via the system bus 16 between the memory MEM1 and the plurality of MAC circuits 21 in the MAC unit 20, for example. The DMA controller DMAC2 controls data transfer between the memory MEM2 and the plurality of MAC circuits 21 in the MAC unit 20.

For example, the DMA controller DMAC1 sequentially reads the plurality of weight parameters WP from the memory MEM1. Meanwhile, the DMA controller DMAC2 sequentially reads the plurality of pieces of data DT copied in advance from the memory MEM2. Each of the plurality of MAC circuits 21 in the MAC unit 20 performs a product-sum operation to the plurality of weight parameters WP from the DMA controller DMAC1 and the plurality of pieces of data DT from the DMA controller DMAC2. Further, although the details will be described later, each of the plurality of MAC circuits 21 appropriately stores a product-sum operation result in the buffer BUFi.

### Details of Neural Network Engine

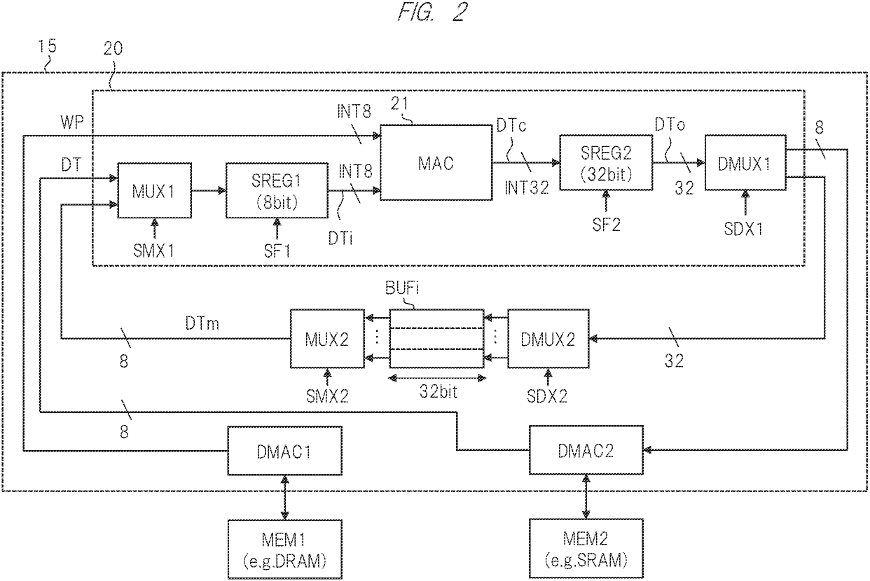

FIG. 2 is a circuit block diagram showing a detailed configuration example around a neural network engine in FIG. 1. The neural network engine 15 shown in FIG. 2 includes a MAC unit 20, a buffer BUFi, and two DMA controllers DMAC1, DMAC2 as described in FIG. 1. In the MAC unit 20 in FIG. 2, by using as a representative one MAC circuit 21 out of the plurality of MAC circuits 21 described in FIG. 1, a detailed configuration example around the one MAC circuit 21 is shown. In addition to the MAC circuit 21, the MAC unit 20 includes a multiplexer MUX1, a preceding-stage shift register SREG1, a subsequent-stage shift register SREG2, and a demultiplexer DMUX1.

The buffer BUFi is composed of, for example, 32-bit width × N flip-flops (N is an integer equal to or greater than 2). A demultiplexer DMUX2 is provided on an input side of the buffer BUFi, and the multiplexer MUX2 is provided on an output side of the buffer BUFi. The buffer BUFi holds output data DTo outputted from the subsequent-stage shift register SREG2 via the two demultiplexers DMUX1, DMUX2. A bit width of the output data DTo is, for example, 32 bits.

The demultiplexer DMUX1 makes a selection of whether to store the output data DTo from the subsequent-stage shift register SREG2 in the memory MEM2 via the DMA controller DMAC2 or in the buffer BUFi via the demultiplexer DMUX2. When the buffer BUFi is selected, the demultiplexer DMUX1 outputs the output data DTo of 32-bit width, and when the memory MEM2 is selected, the demultiplexer DMUX1 outputs the output data DTo of, for example, lower 8 bits or the like in 32 bits. At this time, the remaining 24 bits in the output data DTo are controlled to be zero by quantization / inverse quantization using the preceding-stage shift register SREG1 and the subsequent-stage shift register SREG2, which will be described later.

The demultiplexer DMUX2 makes a selection of which location in the 32-bit width × N buffers BUFi the 32-bit width output data DTo from the demultiplexer DMUX1 is stored at. More specifically, the buffer BUFi is provided in common to the plurality of MAC circuits 21, as shown in FIG. 1, and stores the output data DTo from the plurality of MAC circuits 21 at a location selected by the demultiplexer DMUX2,

The preceding-stage shift register SREG1 sequentially generates a plurality of pieces of quantized input data DTi by quantizing the plurality of pieces of output data DTo sequentially inputted from the buffer BUFi via the two multiplexers MUX2, MUX1 from the buffer BUFi by bit-shifting. Specifically, first, the multiplexer MUX2 selects the output data DTo held at a location of any one of the 32-bit width × N buffers BUFi and, for example, outputs as intermediate data DTm the lower 8 bits of the output data DTo to the multiplexer MUX1.

Also, the multiplexer MUX2 sequentially performs such a processing in time series while changing a position in the buffer BUFi, thereby sequentially outputting a plurality of pieces of intermediate data DTm equivalent to the plurality of pieces of output data DTo. The multiplexer MUX1 selects either the 8-bit width data DT read from the memory MEM2 via the DMA controller DMAC2 or the 8-bit width intermediate data DTm read from the buffer BUFi via the multiplexer MUX2, and outputs the selected data to the preceding-stage shift register SREG1.

The preceding-stage shift register SREG1 is, for example, an 8-bit width register. The preceding-stage shift register SREG1 quantizes the data from the multiplexer MUX1 by using a quantization coefficient Qi of 2^{m} (m is an integer equal to or greater than zero), thereby generating the quantized input data DTi that is in an 8-bit integer (INT8) format. That is, the preceding-stage shift register SREG1 multiplies the inputted data by the quantization coefficient Qi by left-shifting the inputted data by m bits. Assuming that 8 bits can represent 0 to 255 in decimal, the quantization coefficient Qi, that is, a shift amount “m” is determined so that the quantized input data DTi has a value close to 255, for example.

The MAC circuit 21 performs the product-sum operation to the plurality of weight parameters WP sequentially read out from the memory MEM1 via the DMA controller DMAC1 and the plurality of pieces of pieces of quantized input data DTi from the preceding-stage shift register SREG1, thereby generating operation data DTc. The weight parameter WP obtained by learning is usually a value smaller than 1 represented by a 32-bit floating-point number (FP32). Such a weight parameter WP in FP32 format is quantized in advance into INT8 format by using a quantization coefficient Qw, which is 2ⁿ (n is an integer equal to or greater than zero), and is then stored in the memory MEM1.

The MAC circuit 21 includes a multiplier that multiplies two pieces of input data in INT8 format, and an accumulative adder that accumulatively adds multiplication results of the multiplier. The operation data DTc generated by the MAC circuit 21 is, for example, an integer of 16 bits or more, here, in a 32-bit integer (INT32) format.

Incidentally, more specifically, the MAC circuit 21 includes an adder that adds a bias parameter BP to accumulative addition results of the accumulative adder, and an arithmetic unit that computes an activation function for the addition result. Then, the MAC circuit 21 outputs, as operation data DTc, a result obtained by performing addition of the bias parameter BP and calculation of an activation function. In the following, the addition of the bias parameter BP and the calculation of the activation function are ignored for the sake of simplification of a description and will be explained.

The subsequent-stage shift register SREG2 is, for example, a 32-bit width register. The subsequent-stage shift register SREG2 generates the output data DTo by inversely quantizing the operation data DTc from the MAC circuit 21 by bit-shifting. Then, the subsequent-stage shift register SREG2 stores the output data DTo in the buffer BUFi via the two demultiplexers DMUX1, DMUX2.

In particularly, the subsequent-stage shift register SREG2 generates the output data DTo in an INT32 format by multiplying the operation data DTc by the inverse quantization coefficient QR. The inverse quantization coefficient QR is, for example, 1 / (Qi × Qw), that is, 2^{-(m + n)} by using the quantization coefficients Qi (= ₂^{m}) and Qw (= 2ⁿ) described above. In this case, the subsequent-stage shift register SREG2 inversely quantizes the operation data DTc by right-shifting the operation data DTc by k (= m + n) bits.

Incidentally, the shift amount “k” does not necessarily have to be “m + n”. In this case, the output data DTo can be a value that differs from the original value by 2ⁱ times (i is a positive or negative integer). However, in this case, at some stage before the final result in the neural network is obtained, the 2ⁱ-fold deviation can be corrected by the right-shifting or left-shifting in the subsequent-stage shift register SREG2.

Also, the demultiplexers DMUX1, DMUX2 can be configured by a plurality of switches each connecting one input to a plurality of outputs. Similarly, the multiplexers MUX1, MUX2 can be configured by a plurality of switches each connecting a plurality of inputs to one output. On / off of each of the plurality of switches forming the demultiplexers DMUX1, DMUX2 is controlled by selection signals SDX1, SDX2. On / off of each of the plurality of switches forming the multiplexers MUX1, MUX2 is controlled by selection signals SMX1, SMX2.

The selection signals SDX1, SDX2, SMX1, and SMX2 are generated by firmware or the like that controls the neural network engine 15, for example. The firmware appropriately generates the selection signals SDX1, SDX2, SMX1, and SMX2 through a not-shown control circuit of the neural network engine 15 based on a structure of the neural network preset or programmed by the user.

The shift amount “m” of the preceding-stage shift register SREG1 is controlled by a shift signal SF1, and the shift amount “k” of the subsequent-stage shift register SREG2 is controlled by a shift signal SF2. The shift signals SF1, SF2 are also generated by the firmware and the control circuit. At this time, the user can arbitrarily set the shift amounts “m” and “k”.

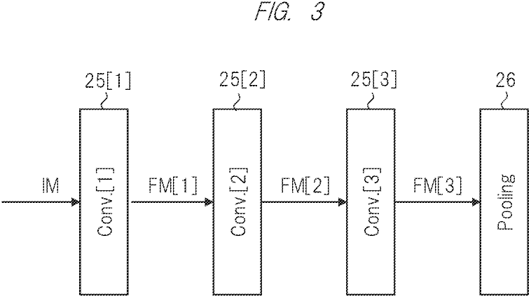

FIG. 3 is a schematic diagram showing a configuration example of a neural network processed by the neural network engine shown in FIG. 2. A neural network shown in FIG. 3 includes three convolutional layers 25 [1], 25 [2], 25 [3] cascade-connected, and a pooling layer 26 connected to its subsequent stage. The convolution layer 25[1] generates data of a feature map FM[1] by, for example, performing a convolution operation with data DT of an input map IM held in the memory MEM2 as an input.

The convolution layer 25 [2] generates data of a feature map FM[2] by performing a convolution operation with the data of the feature map FM[1] obtained by the convolution layer 25 [1] as an input. Similarly, the convolution layer 25[3] generates data of a feature map FM[3] by performing a convolution operation with the data of the feature map FM[2] obtained by the convolution layer 25 [2] as an input. The pooling layer 26 performs a pooling processing with the data of the feature map FM[3] obtained by the convolution layer 25 [3] as an input.

By targeting such a neural network, the neural network engine 15 in FIG. 2 performs, for example, the following processing. First, as a preliminary preparation, the FP32-format weight parameter WP obtained by learning is quantized into an INT8 format, and is then stored in the memory MEM1. Specifically, the INT8-format weight parameter WP is created by multiplying the FP32-format weight parameter WP by the quantization coefficient Qw (= 2ⁿ) and then rounding to an integer.

In the convolution layer 25 [1], the MAC circuit 21 inputs the plurality of INT8-format weight parameters WP[1] sequentially read out from the memory MEM1. Also, the MAC circuit 21 inputs the plurality of pieces of INT8-format data DT sequentially read out from the memory MEM2 via the multiplexer MUX1 and the preceding-stage shift register SREG1. At this time, the preceding-stage shift register SREG1 performs quantization using the quantization coefficient Qi [1] (= 2^{m1}) (m1 is an integer equal to or greater than 0) for each of the plurality of pieces of data DT, that is, performs the left-shifting, thereby generating a plurality of pieces of quantized input data DTi[1]. Incidentally, the plurality of pieces of data DT from the memory MEM2 are data constituting the input map IM.

The MAC circuit 21 sequentially performs a product-sum operation or the like to the plurality of weight parameters WP [1] from the memory MEM1 and the plurality of pieces of quantized input data DTi[1] from the preceding-stage shift register SREG1, thereby outputting the INT32-format operation data DTc[1]. The subsequent-stage shift register SREG2 generates the output data DTo [1] by multiplying the operation data DTc[1] by the inverse quantization coefficient QR [1] . The inverse quantization coefficient QR[1] is, for example, 1 / (Qw • Qi [1]). In this case, the subsequent-stage shift register SREG2 performs the right-shifting.

The output data DTo [1] obtained in this manner is one piece of data out of the plurality of pieces of data constituting the feature map FM[1] . The subsequent-stage shift register SREG2 stores the output data DTo [1] at a predetermined location in the buffer BUFi via the demultiplexers DMUX1, DMUX2. Thereafter, the MAC circuit 21 generates another piece of data out of the plurality of pieces of data constituting the feature map FM[1] by performing the same processing to another plurality of pieces of data DT. This another piece of data is also stored at a predetermined location in the buffer BUFi. In addition, all the pieces of data constituting the feature map FM[1] are stored in the buffer BUFi by the plurality of MAC circuits 21 performing the same processing in parallel.

In the convolution layer 25 [2], the MAC circuit 21 inputs a plurality of INT8-format weight parameters WP[2] read out from the memory MEM1. Also, the MAC circuit 21 inputs a plurality of pieces of intermediate data DTm via the multiplexer MUX1 and the preceding-stage shift register SREG1, the plurality of pieces of intermediate data DTm being sequentially read out from the buffer BUFi via the multiplexer MUX2. At this time, the preceding-stage shift register SREG1 performs, for each of the plurality of pieces of intermediate data DTm, the quantization using a quantization coefficient Qi [2] (= 2^{m2}) (m2 is an integer equal to or greater than 0), that is, performs the left-shifting, thereby generating a plurality of pieces of quantized input data DTi [2] . The plurality of pieces of intermediate data DTm from the buffer BUFi are data constituting the feature map FM[1].

In this manner, in the configuration example of FIG. 2, providing the buffer BUFi makes it possible to store the data forming the feature map FM[1] in the buffer BUFi instead of the memory MEM2. Consequently, access frequency to the memory MEM2 decreases, and the required memory bandwidth can be reduced.

The MAC circuit 21 generates the INT32-format operation data DTc[2] by sequentially performing the product-sum operation to the plurality of weight parameters WP [2] from the memory MEM1 and the plurality of pieces of quantized input data DTi[2] from the preceding-stage shift register SREG1. The subsequent-stage shift register SREG2 generates the output data DTo [2] by multiplying the operation data DTc [2] by the inverse quantization coefficient QR [2] . The inverse quantization coefficient QR[2] is, for example, 1 / (Qw • Qi [2]). In this case, the subsequent-stage shift register SREG2 performs the right-shifting.

The output data DTo[2] obtained in this manner is one piece of data out of the plurality of pieces of data constituting the feature map FM[2] . The subsequent-stage shift register SREG2 stores the output data DTo[2] in the buffer BUFi via the demultiplexers DMUX1, DMUX2. Then, similarly to a case of the convolutional layer 25 [1] , all the pieces of data constituting the feature map FM[2] are stored in the buffer BUFi.

Also in the convolutional layer 25 [3] , the same processing as that to the convolutional layer 25 [2] is performed. At this time, a quantization coefficient Qi[3] (= 2^{m3}) is used in the preceding-stage shift register SREG1, and an inverse quantization coefficient QR[3], for example, 1 / (Qw • Qi [3] ) is used in the subsequent-stage shift register SREG2. However, in the convolutional layer 25 [3], unlike respective cases of the convolutional layers 25 [1] and 25 [2], the output data DTo[3] forming the feature map FM[3] is stored in the memory MEM2 via the demultiplexer DMUX1 and the DMA controller DMAC2. Thereafter, for example, the processor 17 shown in FIG. 1 performs the pooling processing to the feature map FM[3] stored in the memory MEM2.

In such a behavior, a value of the output data DTo usually decreases as it passes through the convolutional layers 25 [1], 25 [2], 25 [3]. In this case, the quantization coefficient Qi of the preceding-stage shift register SREG1 can be increased by an amount corresponding to a decrease in the value of the output data DTo. Here, in order to reduce the quantization error, it is desirable to set the quantization coefficient Qi at a value as large as possible so that the quantized input data DTi falls within an integer range of the INT8 format. Therefore, for example, the quantization error can be reduced by setting the quantization coefficient Qi [2] (= 2^{m2}) and the quantization coefficient Qi [3] (= 2^{m3}) so as to meet m2 < m3.

However, a method of reducing the quantization error is not necessarily limited to a method of determining m2 < m3, and another method may be used. Whichever method is used, the reducing method can be handled by appropriately determining the shift amount “m” of the preceding-stage shift register SREG1 and the shift amount “k” of the subsequent-stage shift register SREG2 according to the setting or programming by the user. Further, the inverse quantization coefficient QR is not limited to 1 / (Qw • Qi), and can also be changed as appropriate. In this case, as described above, 2ⁱ-fold deviations may occur, but the 2ⁱ-fold deviations may be corrected by the subsequent-stage shift register SREG2 so as to target the final result, that is, the out data DTo[3] forming the feature map FP[3].

### Main Effect of First Embodiment

As described above, in the semiconductor device according to the first embodiment, providing the preceding-stage shift register SREG1 and the subsequent-stage shift register SREG2 makes it possible to typically provide a mechanism for efficiently reducing the quantization error in the neural network. As a result, it becomes possible to sufficiently maintain the accuracy of the inference using the neural network. Further, providing the buffers BUFi makes it possible to reduce the memory bandwidth. Then, reduction in the processing load due to the quantization, cutdown of the required memory bandwidth, and the like make it possible to shorten the time required for the inference.

Incidentally, it is assumed as a comparative example that the preceding-stage shift register SREG1, the subsequent-stage shift register SREG2, and the buffer BUFi are not provided. In this case, for example, the data of the feature maps FM [1], FM [2] obtained from the convolutional layers 25 [1], 25 [2] needs to be stored in the memory MEM2. Further, a quantization / inverse quantization processing or the like using the processor 17 is required separately. As a result, the memory bandwidth is increased, and the time required for the inference can also be increased due to necessity of a processing by the processor 17.

### Second Embodiment

### Details of Neural Network Engine

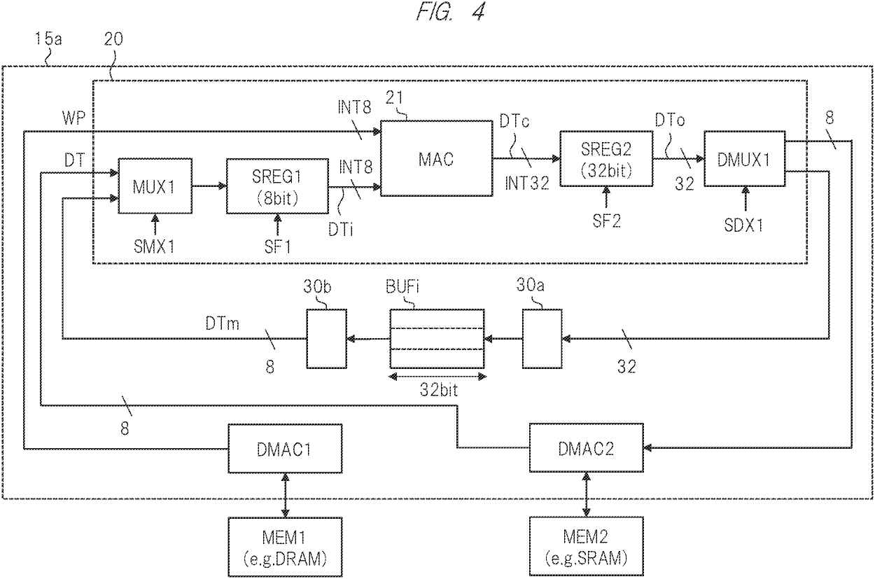

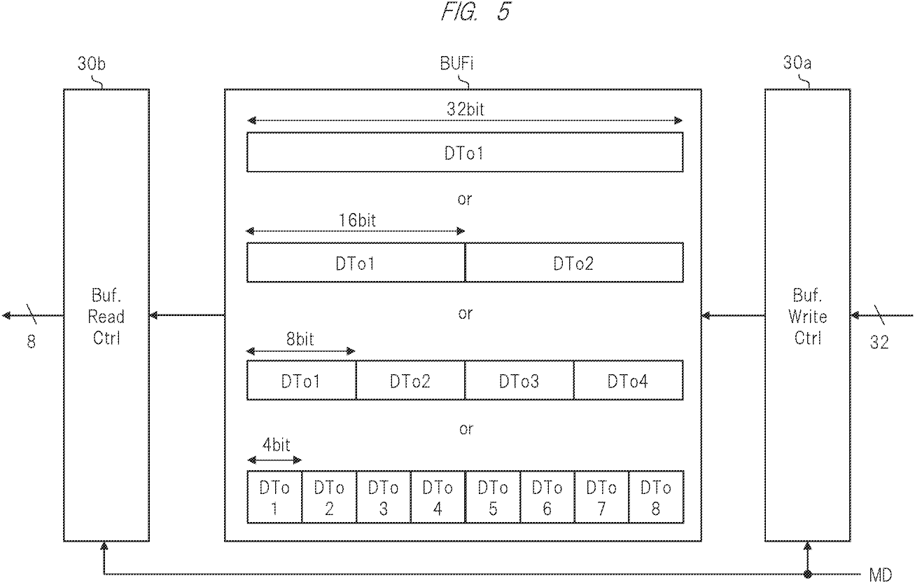

FIG. 4 is a circuit block diagram showing a detailed configuration example around a neural network engine in a semiconductor device according to a second embodiment. FIG. 5 is a schematic diagram for explaining an operation example of a buffer controller in FIG. 4. Unlike the configuration example shown in FIG. 2, a neural network engine 15a shown in FIG. 4 includes a write buffer controller 30a on an input side of the buffer BUFi, and a read buffer controller 30b on an output side of the buffer BUFi.

Each of the buffer controllers 30a, 30b variably controls a bit width of the output data DTo outputted from the subsequent-stage shift register SREG2 via the demultiplexer DMUX1. Specifically, as shown in FIG. 5, each of the buffer controllers 30a, 30b controls the bit width of the output data DTo to any one of 2^{j} bits such as 32 bits, 16 bits, 8 bits, or 4 bits based on the mode signal MD.

When the bit width of the output data DTo is controlled to 32 bits, each of the buffer controllers 30a, 30b controls write / write to the buffer BUFi by using the buffer BUFi, which is physically formed in a 32-bit width, as a 32-bit width buffer. Meanwhile, when the bit width of the output data DTo is controlled to 16 bits, each of the buffer controllers 30a, 30b regards the buffer BUFi configured with a 32-bit width as a 16-bit width × 2 buffers, and controls the write / read. Similarly, when the bit width of the output data DTo is controlled to 8 bits or 4 bits, each of the buffer controllers 30a, 30b regards the buffers BUFi as 8-bit width × 4 buffers or 4-bit width × 8 buffers.

For example, when the bit width of the output data DTo is controlled to 8 bits, each of the buffer controllers 30a, 30b can store, in the buffer BUFi configured with a 32-bit width, four pieces of output data DTol to DTo4 inputted from the MAC circuit 21 via the subsequent-stage shift register SREG2 and the like. This makes it possible to efficiently use the buffer BUFi and reduce power consumption associated with the write / read to the buffer BUFi.

Particularly, in a case of the neural network as shown in FIG. 3, the value of the output data DTo can be controlled so as to decrease each time it passes through the convolution layers 25 [1] to 25 [3]. In this case, the bit width of the output data DTo can be reduced each time it passes through the convolution layers 25 [1] to 25 [3]. Incidentally, the write buffer controller 30a can be configured, for example, by combining a plurality of demultiplexers. Similarly, the read buffer controller 30b can be configured, for example, by combining a plurality of multiplexers.

### Main Effect of Second Embodiment

As described above, using the semiconductor device according to the second embodiment makes it possible to obtain various effects similar to those described in the first embodiment. In addition to this, providing the buffer controllers 30a, 30b makes it possible to efficiently use the buffers BUFi.

### Third Embodiment

### Outline of Semiconductor Device

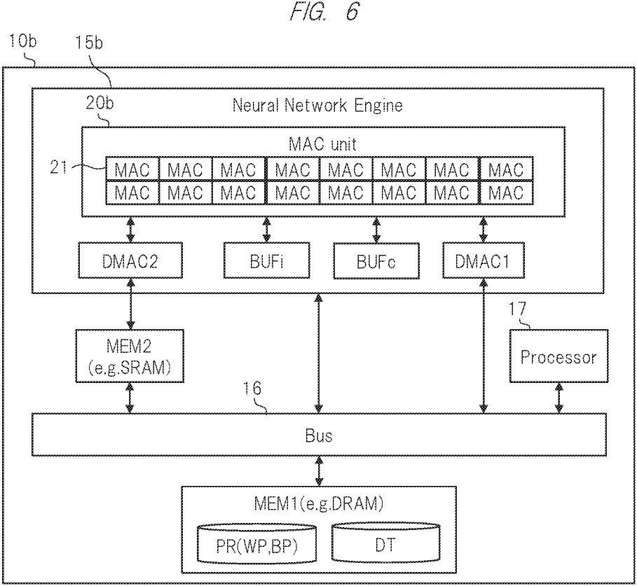

FIG. 6 is a schematic diagram showing a configuration example of a main part in a semiconductor device according to a third embodiment. A semiconductor device 10b shown in FIG. 6 has a buffer BUFc in a neural network engine 15b in addition to a configuration similar to that of FIG. 1. The buffer BUFc is configured by, for example, an SRAM or the like unlike the buffer BUFi configured by the flip-flops or the like. For example, capacity of the buffer BUFi is several tens of kilobytes or less, and capacity of the buffer BUFc is several megabytes or more.

### Details of Neural Network Engine

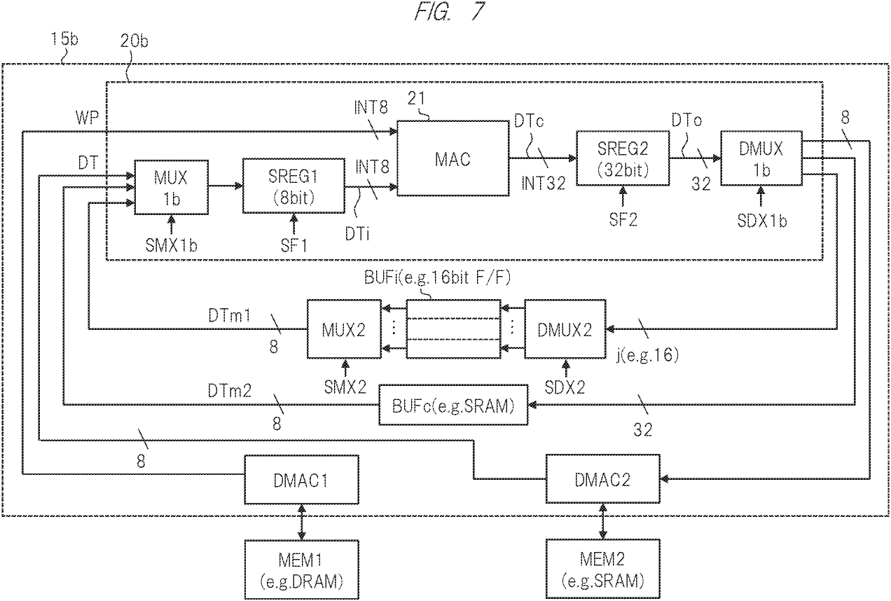

FIG. 7 is a circuit block diagram showing a detailed configuration example around a neural network engine in FIG. 6. A neural network engine 15b shown in FIG. 7 differs from the configuration example shown in FIG. 2 in the following three points. The first difference is that the buffer BUFc is added in addition to the buffer BUFi. The buffer BUFc is configured so as to have the same bit width as that of the subsequent-stage shift register SREG2, and is accessed with a 32-bit width, for example.

The second difference is that the buffer BUFi is configured so as to have a bit width smaller than the bit width of the subsequent-stage shift register SREG2 and, for example, is configured so as to have a 16-bit width. The third difference is that the MAC unit 20b includes a demultiplexer DMUXlb and a multiplexer MUXlb different from those in FIG. 2 due to the addition of the buffer BUFc. The demultiplexer DMUXlb makes, based on a selection signal SDX1b, a selection of which one of the memory MEM2, buffer BUFi, or buffer BUFc the output data DTo from the subsequent-stage shift register SREG2 is stored in. When the buffer BUFi is selected, the buffer BUFi stores, for example, the lower 16 bits in the 32-bit output data DTo.

The multiplexer MUXlb selects, based on the selection signal SMX1b, any one of the data DT held in the memory MEM2, the output data DTo held in the buffer BUFi, or the output data DTo held in the buffer BUFc, and outputs it to the preceding-stage shift register SREG1. The output data DTo held in the buffer BUFi becomes intermediate data DTm1 similarly to the case of FIG. 2. Similarly, the output data DTo held in the buffer BUFc becomes intermediate data DTm2. All of the data DT and the two pieces of intermediate data DTm1 and DTm2 are configured with 8-bit widths or the like.

In the above configuration, the buffer BUFc is larger in capacity at the same area than the buffer BUFi. Meanwhile, the buffer BUFi is faster in an access speed than the buffer BUFc. Here, when the bit width of the output data DTo is large, the required buffer capacity becomes also large. However, if all the buffers are configured by flip-flops, a speed can be increased, but there is concern about an increase in area. Therefore, the two buffers BUFi, BUFc are provided here, and the two buffers BUFi, BUFc are switched according to the bit width of the output data DTo, in other words, the effective bit width.

If the bit width of the output data DTo is greater than 16 bits, the buffer BUFc is selected as a storage destination of the output data DTo. Meanwhile, when the bit width of the output data DTo is 16 bits or less, the buffer BUFi is selected as a storage destination of the output data DTo. As described in the second embodiment, the bit width of the output data DTo may become smaller each time it passes through the convolutional layer. In this case, the buffer BUFc can be used on an initial-stage side of the convolutional layer, and the buffer BUFi can be used on a final-stage side of the convolutional layer.

### Main Effect of Third Embodiment

As described above, using the semiconductor device according to the third embodiment makes it possible to obtain various effects similar to those described in the first embodiment. In addition to this, providing the two buffers BUFi, BUFc makes it possible to improve a balance between the area and the speed.

### Fourth Embodiment

### Details of Neural Network Engine

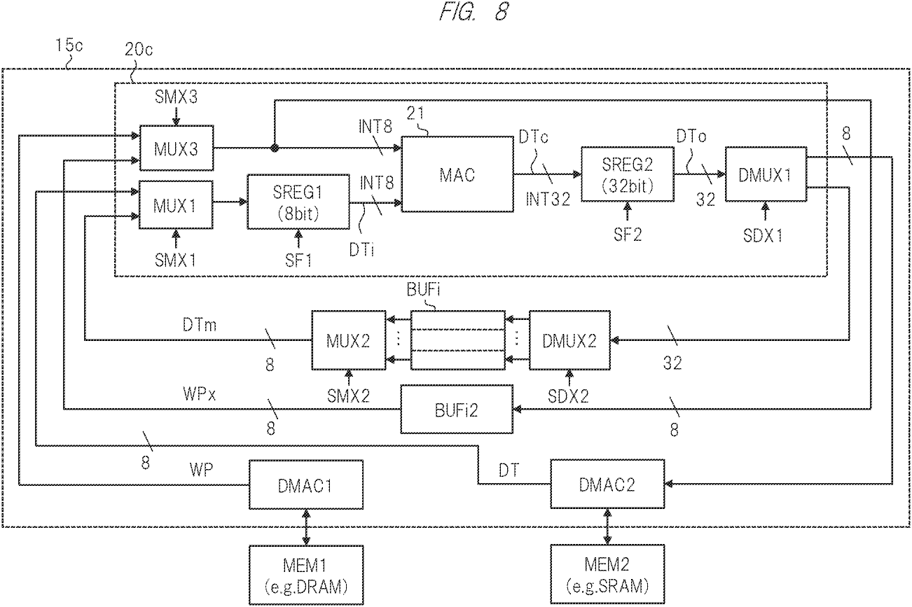

FIG. 8 is a circuit block diagram showing a detailed configuration example around a neural network engine in a semiconductor device according to a fourth embodiment. A neural network engine 15c shown in FIG. 8 differs from the configuration example shown in FIG. 2 in the following two points. The first difference is that a buffer BUFi2 is added in addition to the buffer BUFi. The buffer BUFi2 is configured by, for example, 8-bit width × M flip-flops. The buffer BUFi2 holds a parameter obtained by branching from one input of the MAC circuit 21, for example, a weight parameter WP.

The second difference is that the MAC unit 20c further includes a multiplexer MUX3 with the addition of the buffer BUFi2. The multiplexer MUX3 selects, based on a selection signal SMX3, either the weight parameter WP held in the memory MEM1 or the weight parameter WPx held in the buffer BUFi2, and outputs it to the MAC circuit 21.

The plurality of weight parameters WP are repeatedly used in a processing of the neural network engine 15c for one convolutional layer. For example, in obtaining one piece of data out of the feature map FM [1] shown in FIG. 3, a certain plurality of weight parameters WP are used and, then, in obtaining another piece of data in the feature map FM[1], the plurality of weight parameters WP having the same value are used. Consequently, in using the plurality of weight parameters WP in second and subsequent times, the access frequency to the memory MEM1 can be decreased by reading the plurality of weight parameters WP from the buffer BUFi2.

### Main Effect of Fourth Embodiment

As described above, using the semiconductor device according to the fourth embodiment makes it possible to obtain various effects similar to those described in the first embodiment. In addition to this, providing the buffer BUFi2 makes it possible to decrease the access frequency to the memory MEM1 and cutdown the required memory bandwidth.

In the foregoing, the invention made by the inventor of the present invention has been concretely described based on the embodiments. However, it is needless to say that the present invention is not limited to the foregoing embodiments and various modifications and alterations can be made within a range not departing from the scope of the present invention.

What is claimed is:

1. A semiconductor device executing a neural network processing, the semiconductor device comprising:
a first buffer holding output data;
a first shift register sequentially generating a plurality of pieces of quantized input data by quantizing a plurality of pieces of output data sequentially inputted from the first buffer by bit-shifting, the plurality of pieces of output data being composed of the output data;
a product-sum operator generating operation data by performing a product-sum operation to a plurality of parameters and the plurality of pieces of quantized input data from the first shift register; and
a second shift register generating the output data by inversely quantizing the operation data from the product-sum operator by bit-shifting, and storing the output data in the first buffer.

2. The semiconductor device according to claim 1, further comprising a memory holding the plurality of parameters,
wherein the plurality of parameters are quantized in advance and are stored in the memory, and
wherein each of plurality of pieces of quantized input data and the plurality of parameters is an integer of 8 bits or less.

3. The semiconductor device according to claim 1,
wherein the first buffer is configurated by a flip-flop.

4. The semiconductor device according to claim 3, further comprising:
a second buffer holding the output data and configured by a SRAM;
a demultiplexer making a selection of which one of the first buffer of the second buffer the output data is stored in; and
a multiplexer selecting any one of the output data held in the first buffer or the output data held in the second buffer, and outputting it to the first shift register.

5. The semiconductor device according to claim 4,
wherein a bit width of the first buffer is smaller than a bit width of the second shift register, and
wherein a bit width of the second buffer is the same as a bit width of the second shift register.

6. The semiconductor device according to claim 1, further comprising a buffer controller variously controlling a bit width of the output data.

7. A semiconductor device configured by one semiconductor chip, the semiconductor device comprising:
a neural network engine executing a neural network processing;
one or more memories holding a plurality of pieces of data and a plurality of parameter;
a processor; and
a bus connecting the neural network engine, the one or more memories, and the processor to one another,
wherein the neural network engine includes:
a first buffer holding output data;
a first shift register sequentially generating a plurality of pieces of quantized input data by quantizing a plurality of pieces of output data sequentially inputted from the first buffer by bit-shifting, the plurality of pieces of output data being composed of the output data;
a product-sum operator generating operation data by performing a product-sum operation to the plurality of parameters from the one or more memories and the plurality of pieces of quantized input data from first shift register; and
a second shift register generating the output data by inversely quantizing the operation data from the product-sum operator by bit-shifting, and storing the output data in the first buffer.

8. The semiconductor device according to claim 7,
wherein the plurality of parameters are quantized in advance and are stored in the one or more memories,
wherein each of the plurality of pieces of quantized input data and the plurality of parameters is an integer of 8 bits or less.

9. The semiconductor device according to claim 7,
wherein the first buffer is configured by a flip-flop.

10. The semiconductor device according to claim 9,
wherein the neural network engine further includes:
a second buffer holding the output data and is configured by a SRAM;
a demultiplexer making a selection of which one of the first buffer or the second buffer the output data is stored in; and
a multiplexer selecting any one of the output data held in the first buffer or the output data held in the second buffer, and outputting it to the first shift register.

11. The semiconductor device according to claim 10,
wherein a bit width of the first buffer is smaller than a bit width of the second shift register, and
wherein a bit width of the second buffer is the same as a bit width of the second shift register.

12. The semiconductor device according to claim 7,
wherein the neural network engine further includes a buffer controller variously controlling a bit width of the output data.
